(19) United States
(12) Patent Application Publication
(10) Pub. No.: US 2025/0301709 A1
(43) Pub. Date: Sep. 25, 2025

(54) THIN FILM TRANSISTOR

(71) Applicant: DONGWOO FINE-CHEM CO., LTD., Iksan-si (KR)

(72) Inventors: Byoungin KIM, Iksan-si (KR); Geun Wang JI, Iksan-si (KR); Kyong Ho KIM, Iksan-si (KR)

(73) Assignee: DONGWOO FINE-CHEM CO., LTD., Iksan-si (KR)

(21) Appl. No.: 19/082,379

(22) Filed: Mar. 18, 2025

(30) Foreign Application Priority Data
Mar. 19, 2024 (KR) 10-2024-0037670

(51) Int. Cl. H10D 30/67

(52) U.S. Cl. CPC H10D 30/6757; H10D 30/6729; H10D 30/6732; H10D 30/6737; H10D 30/6755

(57) ABSTRACT

A thin film transistor includes a substrate, a gate electrode formed on the substrate, an insulation layer covering the gate electrode, source/drain electrodes, which are formed horizontally spaced apart on the insulation layer and comprise a conductive metal pattern and a conductive oxide layer covering the conductive metal pattern, a semiconductor layer bonded to the spaced apart space of the source/drain electrodes, and a passivation layer covering the source/drain electrodes and the semiconductor layer.

### CROSS REFERENCE TO RELATED APPLICATIONS

The instant application claims priority based on Korean Patent Application No. 10-2024-0037670 filed Mar. 19, 2024, the entire contents of which are hereby incorporated by reference.

### TECHNICAL FIELD

The present invention relates to a thin film transistor. Particularly, the present invention relates to a thin film transistor capable of maintaining or increasing the conductivity of source/drain electrodes by preventing a pattern of conductive metal constituting the source/drain electrodes from being etched away in a semiconductor layer formation process.

### BACKGROUND ART

An image display device, such as a liquid crystal display, is a device that injects liquid crystal between two substrates on which transparent electrodes are formed to obtain an image effect by utilizing the difference in refractive index of light due to the anisotropy of the liquid crystal.

The liquid crystal display includes a display panel, a panel drive part, and the like. The display panel includes a plurality of gate lines and data lines. The panel drive part includes a gate drive part that provides a gate signal to the plurality of gate lines and a data drive part that provides a data voltage to the data lines.

The display panel includes a thin film transistor (TFT) arranged in each pixel to open and close the pixel. The thin film transistors act as switches. Active matrix liquid crystal displays (AM-LCDs), in which the first electrode is switched on and off on a pixel-by-pixel basis and the second electrode is used as a common electrode, are widely used and are superior in resolution and video display capability.

Liquid crystal displays use wiring to relay signals. The wiring is usually composed of a conductive metal with a low resistivity value and strong corrosion resistance, such as aluminum, aluminum alloy, copper, etc.

However, when manufacturing thin film transistors, the etchant (e.g., acetic acid, organic acid, hydrochloric acid, perchloric acid, etc.) used in the process of forming the semiconductor layer (e.g., IGZO) has the property of etching conductive metals such as aluminum and copper. As a result, when a semiconductor layer such as IGZO is formed after forming source/drain electrodes with a conductive metal, the conductive metal of the source/drain electrodes is etched away, causing a problem that reduces the conductivity of the source/drain electrodes.

### DISCLOSURE

### Technical Problem

It is an object of the present invention to maintain or increase the conductivity of source/drain electrodes by preventing the conductive metal constituting the source/drain electrodes from being etched away in a semiconductor layer formation process when manufacturing a thin film transistor.

### Technical Solution

To achieve the purpose, a thin film transistor of the present invention includes a substrate, a gate electrode, an insulation layer, source/drain electrodes, a semiconductor layer, a passivation layer, and the like.

The substrate supports the gate electrode and the like formed thereon, and a rigid substrate such as glass or a flexible substrate such as a polymer organic material may be used.

The gate electrode is formed on the substrate.

The insulation layer is formed while covering the gate electrode.

The source/drain electrodes are formed horizontally spaced apart on the insulation layer. The source/drain electrode is composed of a conductive metal pattern and a conductive oxide layer covering the conductive metal pattern.

The semiconductor layer is formed in the spaced apart space of the source/drain electrodes.

The passivation layer is formed while covering the source/drain electrodes and the semiconductor layer.

In the thin film transistor of the present invention, the source/drain electrode is formed in a structure in which the conductive oxide layer covers an exposed surface of the conductive metal pattern.

In the thin film transistor of the present invention, the conductive oxide layer has a width of 0.5 μm or more from the exposed surface (boundary surface) of the conductive metal pattern.

In the source/drain electrode of the thin film transistor of the present invention, the conductive metal pattern is formed to have a width of 3 to 15 μm and the conductive oxide layer is formed to have a width of 4 to 24 μm.

In the thin film transistor of the present invention, the gate electrode and conductive metal pattern are composed of molybdenum-niobium (MoNb), and the semiconductor layer is composed of IGZO (indium gallium zinc oxide).

An image display device according to the present invention comprises a thin film transistor described above.

An imaging device according to the present invention comprises a thin film transistor described above.

A photodiode device according to the present invention comprises a thin film transistor described above.

### Advantageous Effects

The transistor of the present invention having such a configuration can prevent the conductive metal pattern of the source/drain electrodes from being etched away in the semiconductor layer formation process by forming a structure in which a conductive oxide layer such as ITO having resistance to the semiconductor layer (e.g., IGZO) etchant surrounds and protects the conductive metal pattern of the source/drain electrodes. As a result, the conductivity of the source/drain electrodes can be maintained or increased.

In addition, the transistor of the present invention can prevent the conductive metal pattern of the source/drain electrodes from being etched away by the semiconductor layer (e.g., IGZO) etchant by forming a conductive oxide layer wider than the conductive metal pattern forming the source/drain electrodes by 0.5 μm or more in width to cover it.

### DESCRIPTION OF DRAWINGS

FIG. 1 is a cross-sectional view of a thin film transistor according to the present invention.

FIG. 2 is a plan view of a thin film transistor according to the present invention.

### BEST MODE

Hereinafter, the present invention will be described in more detail.

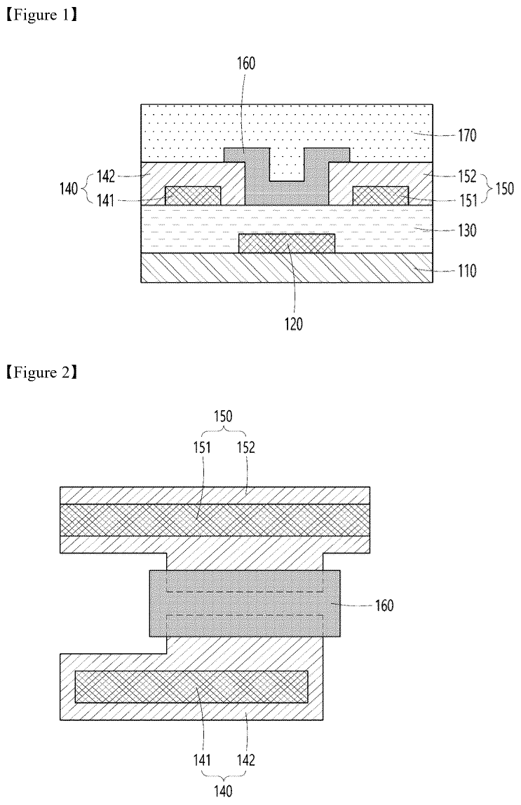

FIG. 1 is a cross-sectional view of a thin film transistor according to the present invention, and FIG. 2 is a plan view of a thin film transistor according to the present invention.

As shown in FIGS. 1 and 2, a thin film transistor of the present invention may include a substrate 110, a gate electrode 120, an insulation layer 130, a source electrode 140, a drain electrode 150, a semiconductor layer 160, a passivation layer 170, and the like.

The substrate 110 supports the gate electrode 120 and the like formed thereon, and may be a rigid or flexible substrate. The rigid substrate may be made of glass, quartz, or the like. The flexible substrate may be made of a polymeric organic material or the like.

The gate electrode 120, which applies a control (driving) signal to the thin film transistor, can be formed on the substrate 110.

The gate electrode 120 can be composed of a conductive metal. The conductive metal may be a single metal such as silver (Ag), copper (Cu), gold (Au), aluminum (Al), platinum (Pt), palladium (Pd), chromium (Cr), tungsten (W), titanium (Ti), tantalum (Ta), iron (Fe), cobalt (Co), nickel (Ni), zinc (Zn), tellurium (Te), vanadium (V), niobium (Nb), molybdenum (Mo), etc. or an alloy thereof (e.g., MoNb, etc.).

The gate electrode 120 can be formed by forming a conductive metal layer on the substrate 110 by sputtering or the like, forming a pattern by applying/pattern-exposing/developing a resist layer on the conductive metal layer, wet or dry etching the conductive metal layer corresponding to the pattern of the resist layer, peeling off the resist layer, and cleaning. For example, an etchant composition containing hydrogen peroxide, a fluorine compound, an azole-based compound, a sulfonic acid, an organic (per) acid, and/or an organic salt can be used for wet etching of the conductive metal layer. More specifically, the etchant composition may contain 15 to 25 wt % of hydrogen peroxide, 0.1 to 2 wt % of a fluorine compound, 0.1 to 1 wt % of an azole-based compound, 0.3 to 1 wt % of a sulfonic acid, 0.01 to 3 wt % of one or more compounds selected from an organic (per) acid and an organic salt, and the balance of water.

The insulation layer 130 functions as a gate insulator that insulates the gate electrode 120 and the source electrode 140/drain electrode 150/semiconductor layer 160, and can be formed to cover the top of the gate electrode 120.

The insulation layer 130 may be formed of an inorganic or organic insulator. The inorganic insulator may be, for example, silicon oxide (SiOx), silicon nitride (SiNx), or the like. The organic insulator may be, for example, a polyacrylate resin, an epoxy resin, a phenolic resin, a polyamide resin, a polyimide resin, an unsaturated polyester resin, a polyphenylenether resin, a polyphenylenesulfide resin, benzocyclobutene, or the like.

The insulation layer 130 may be formed by applying an insulator on top of the gate electrode 120 and performing a film formation step. The insulator can be applied using any of known coating methods, such as spin coating, die coating, spray coating, roll coating, screen coating, slit coating, dip coating, gravure coating, or the like. The film formation can be performed by thermal curing, UV curing, thermal drying, vacuum drying, or the like, depending on the material properties of the insulator.

The source electrode 140 may be composed of a source conductive metal pattern 141 and a source conductive oxide layer 142 surrounding the top and sides of the source conductive metal pattern 141.

The source conductive metal pattern 141 can be composed of a conductive metal, similarly to the gate electrode 120. The conductive metal can be a single metal, such as silver (Ag), copper (Cu), gold (Au), aluminum (Al), platinum (Pt), palladium (Pd), chromium (Cr), tungsten (W), titanium (Ti), or an alloy thereof (e.g., MoNb, etc.), for example.

The source conductive metal pattern 141 can be formed by forming a conductive metal layer on the insulation layer 130 by sputtering or the like, forming a pattern by applying/pattern-exposing/developing a resist layer on the conductive metal layer, wet or dry etching the conductive metal layer corresponding to the pattern of the resist layer, peeling off the resist layer, and cleaning, similarly to formation of the gate electrode 120.

The source conductive metal pattern 141 can be formed to have a width of 15 μm or less to correspond to a pixel size of 119 μm×119 μm in a high-resolution image display device. The source conductive metal pattern 141 needs to have a width of 3 μm or more to ensure the minimum conductivity required for signal processing. Therefore, the source conductive metal pattern 141 may be preferably formed to have a width of 3 to 15 μm.

The source conductive oxide layer 142 can be formed to surround the source conductive metal pattern 141, i.e., to cover the top and sides.

The source conductive oxide layer 142 can be made of a transparent conductive oxide, such as tin oxide, zinc oxide, gallium oxide, indium oxide, or the like, either alone or in a mixture. Specifically, at least one selected from the group consisting of ITO (indium tin oxide), IZO (indium zinc oxide), IGZO (indium gallium zinc oxide), In₂O₃ (indium oxide), IGO (indium gallium oxide), AZO (aluminum zinc oxide), ITZO (indium tin zinc oxide), GZO (gallium zinc oxide), ZnO (zinc oxide), Sn₂O₃ (tin oxide), TiO₂ (titanium dioxide) may be used.

The source conductive oxide layer 142 can be formed by forming a conductive oxide on the source conductive metal layer 141 by sputtering or the like, forming a pattern by applying/pattern-exposing/developing a resist layer on the conductive oxide layer, wet or dry etching the conductive oxide layer corresponding to the pattern on the resist layer, peeling off the resist layer, and cleaning. For example, a wet etchant containing hydrogen peroxide; an acid having a pKa of less than 1; a fluorine compound comprising an alkali metal; and a metal salt selected from iron(III) chloride, cobalt(III) nitrate, copper(II) nitrate, and iron(II) nitrate can be used to etch the conductive oxide layer.

The source conductive oxide layer 142 can be formed to have a width of 24 μm or less, preferably 21 μm or less, to correspond to a pixel size of 119 μm×119 μm in a high-resolution image display device. The source conductive oxide layer 142 requires a width exceeding 3 μm to cover the source conductive metal pattern 141, which is formed with a width of 3 to 15 μm underneath. Therefore, the source conductive oxide layer 142 can be formed with a width of more than 3 to 24 μm, preferably more than 3 to 21 μm.

The drain electrode 150 may be composed of a drain conductive metal pattern 151 and a drain conductive oxide layer 152 surrounding the drain conductive metal pattern 151, similarly to the source electrode 140.

The drain conductive metal pattern 151 can be composed of a single metal such as silver (Ag), copper (Cu), gold (Au), aluminum (Al), platinum (Pt), palladium (Pd), chromium (Cr), tungsten (W), titanium (Ti), or an alloy thereof (e.g., MoNb, etc.), similarly to the source conductive metal pattern 141.

The drain conductive metal pattern 151 can be formed in the same or similar form in the process of forming the source conductive metal pattern 141.

The drain conductive metal pattern 151 may preferably be formed to have a width of 3 to 15 μm, similarly to the source conductive metal pattern 141.

The drain conductive oxide layer 152 is formed to surround the drain conductive metal pattern 151, similarly to the source conductive oxide layer 142. The drain conductive oxide layer 152 can be made of, for example, tin oxide, zinc oxide, gallium oxide, indium oxide, or the like, either alone or in a mixture. Specifically, at least one selected from the group consisting of ITO (indium tin oxide), IZO (indium zinc oxide), IGZO (indium gallium zinc oxide), In₂O₃ (indium oxide), IGO (indium gallium oxide), AZO (aluminum zinc oxide), ITZO (indium tin zinc oxide), GZO (gallium zinc oxide), ZnO (zinc oxide), Sn₂O₃ (tin oxide), TiO₂ (titanium dioxide) may be used.

The drain conductive oxide layer 152 can be formed in the same or similar form in the process for forming the source conductive oxide layer 142.

The drain conductive oxide layer 152 can be formed to have a width of more than 3 to 24 μm, preferably more than 3 to 21 μm, similarly to the source conductive oxide layer 142.

The semiconductor layer 160 forms a channel layer between the source electrode 140 and the drain electrode 150 in response to the driving signal of the gate electrode 120, and can be formed by filling the gap space between the source electrode 140 and the drain electrode 150 on the insulation layer 130.

The semiconductor layer 160 may be formed from an amorphous semiconductor, such as indium gallium zinc oxide (IGZO). In addition, the semiconductor layer 160 can be formed from at least one selected from the group consisting of ITO (indium tin oxide), ZnO (zinc oxide), Sn₂O₃ (tin oxide), TiO₂ (titanium dioxide), ZnSnO (zinc tin oxide), CdSnO (cadmium tin oxide), GaSnO (gallium tin oxide), TiSnO (titanium tin oxide), InGaZnO (indium gallium zinc oxide), CuAlO (copper aluminum oxide), SrCuO (strontium copper oxide), LaCuOS (lanthanum copper oxide sulfide), GaN (gallium nitride), InGaN (indium gallium nitride), AlGaN (aluminum gallium nitride), CNT (carbon nanotube), and InGaAlN (indium gallium aluminum nitride).

The semiconductor layer 160 can be formed by forming an IGZO layer between the source electrode 140 and the drain electrode 150 and on a part or all of the upper portions thereof, by a method such as sputtering, chemical vapor deposition, plasma-assisted chemical vapor deposition, vacuum deposition, electron beam deposition, ion plating, pulsed laser deposition, or the like, forming a pattern by applying/pattern-exposing/developing a resist layer on the IGZO layer, wet or dry etching the IGZO layer corresponding to the pattern of the resist layer, peeling off the resist layer, and cleaning.

In the process of etching the IGZO layer when forming the semiconductor layer 160, an etchant containing one of acetic acid, citric acid, hydrochloric acid, or perchloric acid, for example, is used in the case of wet etching, and a processing gas comprising a bromine (Br) or iodine (I) containing gas is used in the case of dry etching. Wet etchants or dry etch gases have the property of etching conductive metals such as silver (Ag), copper (Cu), gold (Au), aluminum (Al), or conductive alloys such as molybdenum-niobium (MoNb).

However, according to the present invention, a conductive oxide layer, which is resistant to wet etching solution or dry etching gas of the IGZO layer, covers the conductive metal pattern of the source electrode 140 and the drain electrode 150, unlike the prior art. As a result, damage (i.e., etching) of the conductive metal pattern, which determines the conductivity (or conductance) of the source electrode 140 and the drain electrode 150, can be effectively blocked during the formation process of the semiconductor layer 160. Accordingly, the present invention can maintain or increase the conductivity (or conductance) of the source electrode 140 and the drain electrode 150.

Table 1 below shows the results of measuring whether the conductive metal pattern (MoNb) is etched according to the cover width of the conductive oxide layer (ITO) when the IGZO layer is wet-etched with acetic acid. Here, if etching of the conductive metal pattern occurs, it is marked with ‘∘’, and if etching does not occur, it is marked with ‘x’.

TABLE 1

| Cover width of conductive | Whether conductive metal pattern |
|---|---|
| oxide layer (ITO) (μm) | (MoNb) is etched (∘, x) |
| 2.0 | x |
| 1.9 | x |
| 1.8 | x |
| 1.7 | x |
| 1.6 | x |
| 1.5 | x |
| 1.4 | x |
| 1.3 | x |
| 1.2 | x |
| 1.1 | x |
| 1.0 | x |
| 0.9 | x |
| 0.8 | x |
| 0.7 | x |
| 0.6 | x |
| 0.5 | x |
| 0.4 | ∘ |
| 0.3 | ∘ |
| 0.2 | ∘ |

As shown in Table 1 above, it is confirmed that etching does not occur on the MoNb pattern if the cover width of the ITO layer is 0.5 μm or more. Here, the cover width of the ITO layer is measured at right angles (perpendicular) to the exposed surface (boundary surface) of the conductive metal pattern.

As described above, it is preferable to form the width of the conductive metal pattern to be 3 to 15 μm and the width of the conductive oxide layer to be more than 3 to 24 μm (preferably more than 3 to 21 μm). Therefore, considering the etching of the conductive metal pattern (MoNb) according to the cover width of the conductive oxide layer (ITO), the width of the conductive metal pattern can be formed to be 3 to 15 μm and the width of the conductive oxide layer can be formed to be 4 to 24 μm.

The passivation layer 170 covers and protects the source electrode 140, the drain electrode 150, and the semiconductor layer 160, and may be formed of an insulator, such as a curable prepolymer, a curable polymer, a plastic polymer, or the like.

The passivation layer 170 may also use a varnish-type material that can be filmable. Examples of the varnish-type material include polysilicones such as polydimethylsiloxane (PDMS), polyorganosiloxane (POS), or polyimides, or polyurethanes such as spandex. As flexible insulators, these varnish-type materials can increase elongation and dynamic folding capabilities of the product.

The thin film transistors described above can be applied to image display devices. The image display device may include an organic EL display (OLED), a quantum dot nanorod display (QNED), a micro LED, a reflective, transmissive, or transflective LCD, an inorganic EL display (IEL), a plasma display, a field emission display, an electronic paper, and the like.

In addition, the thin film transistors described above can also be applied to imaging devices, photodiode devices, and the like.

Although particular embodiments of the present invention have been shown and described, it will be understood by those skilled in the art that it is not intended to limit the present invention to the preferred embodiments, and it will be obvious to those skilled in the art that various changes and modifications may be made without departing from the spirit and scope of the invention.

The scope of the present invention, therefore, is to be defined by the appended claims and equivalents thereof.

### DESCRIPTION OF REFERENCE NUMERALS

110: substrate
120: gate electrode
130: insulation layer
140: source electrode
141: source conductive metal pattern
142: source conductive oxide layer
150: drain electrode
151: drain conductive metal pattern
152: drain conductive oxide layer
160: semiconductor layer
170: passivation layer

1. A thin film transistor comprising:
a substrate;
a gate electrode formed on the substrate;
an insulation layer covering the gate electrode;
source/drain electrodes formed horizontally spaced apart on the insulation layer, the source/drain electrode comprising a conductive metal pattern and a conductive oxide layer covering the conductive metal pattern;
a semiconductor layer bonded to the spaced apart space of the source/drain electrodes; and
a passivation layer covering the source/drain electrodes and the semiconductor layer.

2. The thin film transistor according to claim 1, wherein the conductive oxide layer covers an exposed surface of the conductive metal pattern in the source/drain electrode.

3. The thin film transistor according to claim 2, wherein the conductive oxide layer has a width of 0.5 μm or more from the exposed surface of the conductive metal pattern.

4. The thin film transistor according to claim 3, wherein the conductive metal pattern is formed to have a width of 3 to 15 μm and the conductive oxide layer is formed to have a width of 4 to 24 μm in the source/drain electrode.

5. The thin film transistor according to claim 1, wherein the gate electrode and conductive metal pattern are composed of molybdenum-niobium (MoNb).

6. The thin film transistor according to claim 1, wherein the semiconductor layer is composed of IGZO (indium gallium zinc oxide).

7. An image display device comprising the thin film transistor according to claim 1.

8. An imaging device comprising the thin film transistor according to claim 1.

9. A photodiode device comprising the thin film transistor according to claim 1.

10. An image display device comprising the thin film transistor according to claim 2.

11. An image display device comprising the thin film transistor according to claim 3.

12. An image display device comprising the thin film transistor according to claim 4.

13. An image display device comprising the thin film transistor according to claim 5.

14. An image display device comprising the thin film transistor according to claim 6.

15. An imaging device comprising the thin film transistor according to claim 2.

16. An imaging device comprising the thin film transistor according to claim 3.

17. An imaging device comprising the thin film transistor according to claim 4.

18. An imaging device comprising the thin film transistor according to claim 5.

19. An imaging device comprising the thin film transistor according to claim 6.
